(19) United States
(12) Patent Application Publication
(10) Pub. No.: US 2010/0252863 A1
(43) Pub. Date: Oct. 7, 2010

(54) SEMICONDUCTOR DEVICE AND MANUFACTURING METHOD FOR THE SAME

(75) Inventor: Hisao KAWASAKI, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/716,693

(22) Filed: Mar. 3, 2010

(30) Foreign Application Priority Data
Apr. 7, 2009 (JP) 2009-093373

(51) Int. Cl. H01L 29/78; H01L 21/336

(52) U.S. Cl. 257/192; 438/285; 257/E29.255; 257/E29.089; 257/E21.441

(57) ABSTRACT

A semiconductor device which reduces a source resistance and a manufacturing method for the same are provided. The semiconductor device has a nitride based compound semiconductor layer arranged on a substrate, an active region which has an aluminum gallium nitride layer arranged on the nitride based compound semiconductor layer, and a gate electrode, source electrode and drain electrode arranged on the active region. The semiconductor device has gate terminal electrodes, source terminal electrodes and drain terminal electrode connected to the gate electrode, source electrode and drain electrode respectively. The semiconductor device has end face electrodes which are arranged on a side face of the substrate by a side where the source terminal electrode is arranged, and which are connected to the source terminal electrode. The semiconductor device has a projection arranged on the end face electrode which prevents solder used in die bonding from reaching the source terminal electrodes.

### CROSS REFERENCE TO RELATED APPLICATION

This application is based upon and claims the benefit of priority from Japanese Patent Application No. 2009-093373, filed on Apr. 7, 2009, the entire contents of which are incorporated herein by reference.

### FIELD OF THE INVENTION

The invention relates to a semiconductor device and a manufacturing method for the same, and relates especially to the semiconductor device in which a grounding inductance is reduced and which operates in microwave band/millimeter wave band/submillimeter band, and the manufacturing method for the same.

### DESCRIPTION OF THE BACKGROUND

An FET (Field Effect Transistor) using compound semiconductor, such as GaN (Gallium Nitride), has outstanding high frequency characteristics and is widely put in practical use as a semiconductor device which operates in microwave band/millimeter wave band/submillimeter wave band.

A conventional semiconductor device is constituted as shown in FIGS. 16 and 17, for example. FIG. 16 shows a plane pattern structure diagram, and FIG. 17 shows a cross sectional view taken along a I-I line in FIG. 16. The semiconductor device has a substrate 10 formed of SiC, gate electrodes 24, source electrodes 20 and drain electrodes which have a plurality of fingers respectively and are arranged on the substrate 10. Further, the semiconductor device has gate terminal electrodes GE1, GE2, GE3 which bundle the fingers of gate electrodes 24, source terminal electrodes SE1, SE2, SE3, SE4 which bundle the fingers of source electrodes 20 and a drain terminal electrode DE which handles the fingers of the drain electrodes 22 arranged on the substrate 10.

In the source terminal electrodes SE1, SE2, SE3, SE4, via holes CS1, CS2, CS3, CS4 are formed in the substrate 10 from the back of the substrate 10. A ground conductor BE is formed on the back of the substrate 10. The source terminal electrode SE1, SE2, SE3, SE4 are electrically connected to the ground conductor BE via the via holes CS1, CS2, CS3, CS4. When grounding a circuit element provided on the substrate 10, the circuit element is electrically connected to the ground conductor BE via the via holes CS1, CS2, CS3, CS4.

A portion where the gate electrodes 24, the source electrodes 20 and the drain electrodes 22 have a plurality of fingers, forms an active region AA which consists of an AlGaN layer 18 and a 2DEG (Two Dimensional Electron Gas) layer 16 as shown in FIG. 17. The 2DEG layer 16 is formed at an interface between the AlGaN layer 18 and a GaN epitaxial growth layer 12. Each of the source electrode 20 and the drain electrode 22 forms an ohmic contact with the AlGaN layer 18, and the gate electrode 24 forms a schottky contact with the AlGaN layer 18.

A grounding inductance which has a bad influence on high frequency characteristics of the semiconductor device can be reduced by forming the via holes CS1, CS2, CS3, CS4 to the source terminal electrodes SE1, SE2, SE3, SE4.

However, a GaN system FET needs a complicated process to form the via holes CS1, CS2, CS3, CS4. In the GaN system FET formed especially on the SiC substrate, since a processing technology itself of SiC, GaN and AlGaN has not been established, a problem arises that a yield in manufacturing the device is low.

Another conventional semiconductor device is constituted as shown in FIG. 18 and FIG. 19, for example. FIG. 18 shows a plane pattern structure diagram and FIG. 19 shows a cross sectional view taken along a II-II line in FIG. 18. A semiconductor device has a substrate 10 which is formed of SiC, and gate electrodes 24, source electrodes 20 and drain electrodes 22 which have a plurality of fingers respectively and are arranged on the substrate 10. The semiconductor device has gate terminal electrodes GE1, GE2, GE3 which handle a plurality of fingers of gate electrodes 24, source terminal electrode SE1, SE2, SE3, SE4 which bundle a plurality of fingers of source electrodes 20 and drain terminal electrode DE which bundles a plurality of fingers of drain electrodes 22 arranged on the substrate 10.

A portion where the gate electrodes 24, the source electrodes 20 and the drain electrodes 22 have a plurality of fingers forms an active region AA which consist of an AlGaN layer 18 and a 2DEG layer 16 like FIG. 17.

End face electrodes SC1, SC2, SC3, SC4 are formed to the source terminal electrode SE1, SE2, SE3, SE4 respectively and are connected to a ground conductor BE formed on the back of the substrate 10. The end face electrodes SC1, SC2, SC3, SC4 are formed of a barrier metal layer 30 which consists of Ti, for example, and a metal layer 32 for grounding which consists of Au formed on the barrier metal layer 30. The grounding inductance which has a bad influence on the high frequency characteristics of the semiconductor device can be reduced by forming such end face electrodes SC1, SC2, SC3, SC4 to the source electrode 20 and the source terminal electrodes SE1, SE2, SE3, SE4.

When grounding a circuit element provided on the substrate 10, the circuit element and the ground conductor BE are electrically connected via the end face electrodes SC1, SC2, SC3, SC4.

In the above-mentioned semiconductor devices, the gate terminal electrodes GE1, GE2, GE3 are connected to a peripheral semiconductor chip by bonding wires etc., and the drain terminal electrode DE is also connected to a peripheral semiconductor chip by bonding wires etc.

JP,PH02-291133A discloses a semiconductor device in which a semiconductor chip has a side face metallized section and at least one side face among four side faces of the chip is not perpendicular to a chip surface.

The end face electrodes SC1, SC2, SC3, SC4 are easy to process compared with the via holes CS1, CS2, CS3, CS4. However, solder used in die bonding rises on the end face electrodes SC1, SC2, SC3, SC4. If the solder reaches the source terminal electrodes SE1, SE2, SE3, SE4 and the source electrodes 20, the solder will react with the source terminal electrodes SE1, SE2, SE3, SE4 and the source electrodes 20. For this reason, the end face electrode SC1, SC2, SC3, SC4 have a problem of causing increase of a source resistance.

### SUMMARY OF THE INVENTION

A purpose of the invention is to provide a semiconductor device for microwave band/millimeter wave band/submillimeter band which can prevent increase in a source resistance, and a manufacturing method for the same.

According to the invention, a semiconductor device including a substrate; a nitride based compound semiconductor layer arranged on the substrate; an active region arranged on the nitride based compound semiconductor layer and having an aluminum gallium nitride layer (AlₓGa₁₋ₓN) (0.1≦x≦1); a gate electrode arranged on the active region; a source electrode arranged on the active region; a drain electrode arranged on the active region; a gate terminal electrode arranged on the nitride based compound semiconductor layer in an extension direction of the gate electrode, and being connected to the gate electrode; a source terminal electrode arranged on the nitride based compound semiconductor layer in an extension direction of the source electrode, and being connected to the source electrode; a drain terminal electrode arranged on the nitride based compound semiconductor layer in an extension direction of the drain electrode, and being connected to the drain electrode; an end face electrode arranged on an end face of the substrate in a source terminal electrode side, and being connected to the source terminal electrode; and a projection arranged on the end face electrode and being configured to prevent solder used in die bonding from reaching the source terminal electrode, is provided.

According to the invention, a semiconductor device including a substrate; a nitride based compound semiconductor layer arranged on the substrate; an active region arranged on the nitride based compound semiconductor layer, and having an aluminum gallium nitride layer (AlₓGa₁₋ₓN) (0.1≦x≦1); a gate electrode arranged on the active region and having a plurality of fingers; a source electrode arranged on the active region and having a plurality of fingers; a drain electrode arranged on the active region and having a plurality of fingers; a gate terminal electrode arranged on the nitride based compound semiconductor layer in an extension direction of the gate electrode, and bundling the plurality of fingers of the gate electrode; a source terminal electrode arranged on the nitride based compound semiconductor layer in an extension direction of the source electrode, and bundling the plurality of fingers of the source electrode; a drain terminal electrode arranged on the nitride based compound semiconductor layer in an extension direction of the drain electrode, and bundling the plurality of fingers of the drain electrode; an end face electrode arranged on an end face of the substrate in a source terminal electrode side, and being connected to the source terminal electrode; and a projection arranged on the end face electrode and being configured to prevent solder used in die bonding from reaching the source terminal electrode, is provided.

According the invention, a method for manufacturing a semiconductor device including forming a nitride based compound semiconductor layer on a substrate; forming an active region including an aluminum gallium nitride layer (AlₓGa₁₋ₓN) (0.1≦x≦1) on the nitride based compound semiconductor layer; forming a gate electrode on the active region; forming a source electrode on the active region; forming a drain electrode on the active region; forming a gate terminal electrode connected to the gate electrode on the nitride based compound semiconductor layer in an extension direction of the gate electrode; forming a source terminal electrode connected to the source electrode on the nitride based compound semiconductor layer in an extension direction of the source electrode; forming a drain terminal electrode connected to the drain electrode on the nitride based compound semiconductor layer in an extension direction of the drain electrode; forming the end face electrode connected to the source terminal electrode on the end face of the substrate in a source terminal electrode side; and forming a projection on the end face electrode, the projection being configured to prevent solder used in die bonding from reaching the source terminal electrode, is provided.

According the invention, a method for manufacturing a semiconductor device including forming a nitride based compound semiconductor layer arranged on a substrate; forming an active region including an aluminum gallium nitride layer (AlₓGa₁₋ₓN) (0.1≦x≦1) on the nitride based compound semiconductor layer; forming a gate electrode having a plurality of fingers on the active region; forming a source electrode having a plurality of fingers on the active region; forming a drain electrode having a plurality of fingers on the active region; forming a gate terminal electrode bundling the plurality of fingers of the gate electrode on the nitride based compound semiconductor layer in an extension direction of the gate electrode; forming a source terminal electrode bundling the plurality of fingers of the source electrode on the nitride based compound semiconductor layer in an extension direction of the source electrode; forming a drain terminal electrode bundling the plurality of fingers of the drain electrode on the nitride based compound semiconductor layer in an extension direction of the drain electrode; forming the end face electrode connected to the source terminal electrode on the end face of the substrate in a source terminal electrode side; and forming a projection on the end face electrode, the projection being configured to prevent solder used in die bonding from reaching the source terminal electrode, is provided.

### BRIEF DESCRIPTION OF THE DRAWINGS

FIG. 1 is a plane view showing a schematic plane pattern structure of a semiconductor device concerning a first embodiment of the invention;

FIG. 2 is a schematic cross sectional view taken along a III-III line in FIG. 1;

FIG. 3 is a cross sectional view showing a schematic cross sectional structure of a constitutional example 1 of the semiconductor device concerning the first embodiment of the invention;

FIG. 4 is a cross sectional view showing a schematic cross sectional structure of a constitutional example 2 of the semiconductor device concerning the first embodiment of the invention;

FIG. 5 is a cross sectional view showing a schematic cross sectional structure of a constitutional example 3 of the semiconductor device concerning the first embodiment of the invention;

FIG. 6 is a schematic cross sectional view explaining a manufacturing method of the semiconductor device concerning the first embodiment of the invention;

FIG. 7 is a cross sectional view showing a schematic cross sectional structure explaining another manufacturing method of the semiconductor device concerning the first embodiment of the invention;

FIG. 8 is an SEM (Scanning Electron Microscope) photograph of the semiconductor device concerning the first embodiment of the invention;

FIG. 9 is a plane view showing a schematic plane pattern structure of a semiconductor device concerning a second embodiment of the invention;

FIG. 10 is a cross sectional view showing a schematic cross sectional structure taken along a V-V line in FIG. 9;

FIG. 11 is a plane view showing a schematic plane pattern structure of a semiconductor device concerning a third embodiment of the invention;

FIG. 12 is a cross sectional view showing a schematic cross sectional structure taken along a VI-VI line in FIG. 11;

FIG. 13 is a plane view showing a schematic plane pattern structure of a semiconductor device concerning a fourth embodiment of the invention;

FIG. 14 is a cross sectional view showing a schematic cross sectional structure of a semiconductor device concerning a fifth embodiment of the invention;

FIG. 15 is a cross sectional view showing a schematic cross sectional structure of a semiconductor device concerning a sixth embodiment of the invention;

FIG. 16 is a plane view showing a schematic plane pattern structure of a semiconductor device concerning a conventional example;

FIG. 17 is a cross sectional view showing a schematic cross sectional structure taken along a I-I line in FIG. 16;

FIG. 18 is a plane view showing a schematic plane pattern structure of a semiconductor device concerning another conventional example; and

FIG. 19 is a cross sectional view showing a schematic cross sectional structure taken along a II-II line in FIG. 18.

### DETAILED DESCRIPTION OF THE INVENTION

Embodiments of the invention will be explained with reference to accompanying drawings. In following description of the drawings, identical or similar numerals are given to identical or similar portions.

### First Embodiment

(Element Structure)

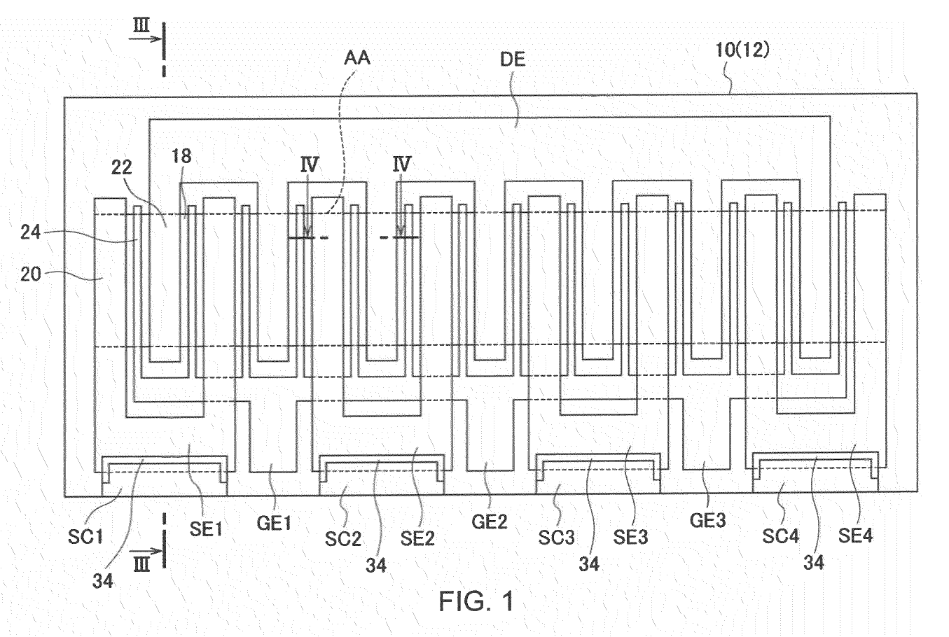

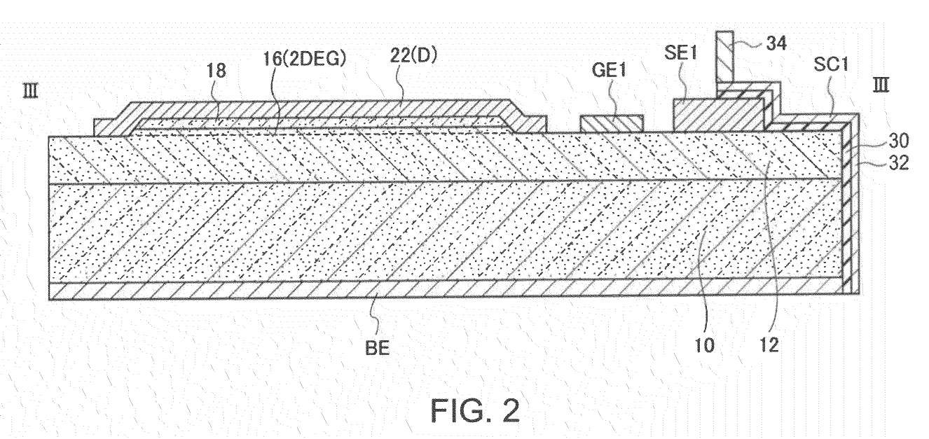

FIG. 1 shows a schematic plane pattern structure of a semiconductor device concerning the first embodiment of the invention. FIG. 2 shows a schematic cross sectional structure taken along a III-III line in FIG. 1.

The semiconductor device has a substrate 10 formed of SiC substrate, a nitride based compound semiconductor layer 12 which has a GaN epitaxial growth layer arranged on the substrate 10, and an aluminum gallium nitride layer (AlxGa₁₋ₓN) (0.1≦x≦1) 18 arranged on the nitride based compound semiconductor layer 12. A 2DEG layer 16 is formed in the nitride based compound semiconductor layer 12 located at an interface between the nitride based compound semiconductor layer 12 and the aluminum gallium nitride layer 18. The semiconductor device has an active region AA which is formed of the aluminum gallium nitride layer 18 and the 2DEG layer 16, a gate electrode 24, a source electrode 20 and a drain electrode 22 which are arranged on the active region AA, and gate terminal electrodes GE1, GE2, GE3 connected to the gate electrode 24, source terminal electrodes SE1, SE2, SE3, SE4 connected to the source electrode 20, and drain terminal electrode DE connected to the drain electrode 22. The semiconductor device further has end face electrodes SC1, SC2, SC3, SC4 which are arranged on an end face of the substrate 10 in the source terminal electrodes SE1, SE2, SE3, SE4 side and are connected to the source terminal electrodes SE1, SE2, SE3, SE4 respectively, and has projections 34 arranged on the end face electrodes SC1, SC2, SC3, SC4 respectively. The projections 34 prevent solder used in die bonding from reaching the source terminal electrodes SE1, SE2, SE3, SE4.

The gate electrode 24, the source electrode 20 and the drain electrode 22 have a plurality of fingers respectively. The gate terminal electrodes GE1, GE2, GE3, the source terminal electrodes SE1, SE2, SE3, SE4, and the drain terminal electrode DE are arranged on the nitride based compound semiconductor layer 12 located in a direction which the gate electrode 24, the source electrode 20 and the drain electrode 22 extend. The gate terminal electrodes GE1, GE2, GE3 bundle the plurality of fingers of the gate electrode 24. The source terminal electrodes SE1, SE2, SE3, SE4 bundle the plurality of fingers of the source electrode 20. The drain terminal electrode DE bundles the plurality of fingers of the drain electrode 22.

The source electrode 20, the drain electrode 22, the source terminal electrodes SE1, SE2, SE3, SE4 and the drain terminal electrode DE are formed of Ti/Al, for example. And the gate electrode 24 and the gate terminal electrodes GE1, GE2, GE3 are formed of Ni/Au, for example.

The aluminum gallium nitride layer 18 between the gate electrode 24 and the source electrode 20, between the gate electrode 24 and the drain electrode 22, under the gate electrode 24, the source electrode 20 and the drain electrode 22, and under the 2DEG layer 16 form the active region AA

A schottky contact is formed between the gate electrode 24 and the aluminum gallium nitride layer 18. An ohmic contact is formed between the source electrode 20 and the aluminum gallium nitride layer 18, and an ohmic contact is formed between the drain electrode 22 and the aluminum gallium nitride layer 18.

The end face electrodes SC1, SC2, SC3, SC4 are formed on the end face of the substrate 10 and are formed to extend on the source terminal electrodes SE1, SE2, SE3, SE4. The projections 34 are arranged to extend on the end face electrodes SC1, SC2, SC3, SC4 on a boundary between the source terminal electrodes SE1, SE2, SE3, SE4 and the end face electrodes SC1, SC2, SC3, SC4.

Each of end face electrodes SC1, SC2, SC3, SC4 has a barrier metal layer 30 and a metal layer 32 for grounding arranged on the barrier metal layers 30.

The barrier metal layer 30 is formed of a Ti layer, or a Ti/Pt layer, for example, and the metal layer 32 for grounding is formed of an Au layer, for example.

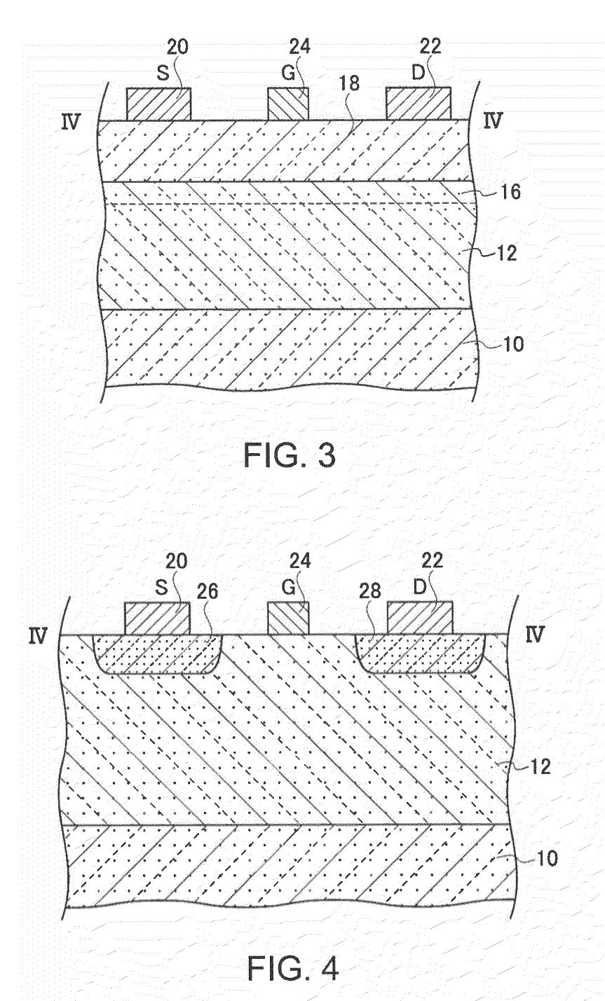

FIGS. 3-5 show schematic cross sectional structures taken along a IV-IV line in FIG. 1, and FIGS. 3-5 correspond to constitutional examples 1-3 of the semiconductor device concerning the first embodiment respectively.

### Constitutional Example 1

As shown in FIG. 3, a semiconductor device has a substrate 10, a GaN epitaxial growth layer 12 arranged on the substrate 10, an aluminum gallium nitride layer (AlₓGa₁₋ₓN) (0.1≦x≦1) 18 arranged on the GaN epitaxial growth layer 12, and a source electrode 20, a gate electrode 24 and a drain electrode 22 which are arranged on the aluminum gallium nitride layer 18 respectively. A 2DEG layer 16 is formed in the GaN epitaxial growth layer 12 at an interface between the GaN epitaxial growth layer 12 and the aluminum gallium nitride layer 18. In the semiconductor device shown in FIG. 3, an HEMT (High Electron Mobility Transistor) is configured.

### Constitutional Example 2

Another constitutional example is shown in FIG. 4. A semiconductor device has a substrate 10, a GaN epitaxial growth layer 12 arranged on the substrate 10, a source region 26 and a drain region 28 arranged in the GaN epitaxial growth layer 12, a source electrode 20 arranged on the source region 26, a gate electrode 24 arranged on the GaN epitaxial growth layer 12 and a drain electrode 22 arranged on the drain region 28.

In the semiconductor device shown in FIG. 4, an MESFET (Metal Semiconductor Field Effect Transistor) is configured.

### Constitutional Example 3

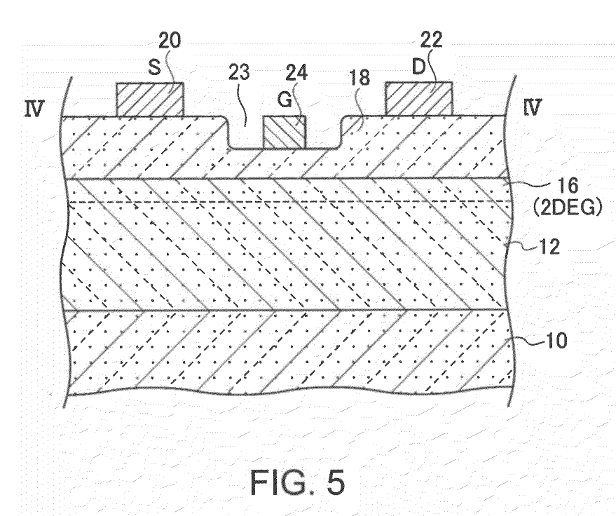

Still another constitutional example is shown in FIG. 5. A semiconductor device has a substrate 10, a GaN epitaxial growth layer 12 arranged on the substrate 10, an aluminum gallium nitride layer (AlₓGa₁₋ₓN) (0.1≦x≦1) 18 arranged on the GaN epitaxial growth layer 12, a source electrode 20 and a drain electrode 22 arranged on the aluminum gallium nitride layer 18, and a gate electrode 24 arranged on a recessed portion 23 of the aluminum gallium nitride layer 18. A 2DEG layer 16 is formed in the GaN epitaxial growth layer 12 at an interface between the GaN epitaxial growth layer 12 and the aluminum gallium nitride layer 18. The semiconductor device shown in FIG. 5 corresponds to the HEMT which has a recess gate structure.

In the above-mentioned embodiment, the nitride based compound semiconductor layer 12 other than the active region AA is used as an electrically inactivity device isolation region. However, as other forming methods of the device isolation region, there is an ion implantation method. The device isolation region can be formed by implanting ions to the aluminum gallium nitride layer 18 and a part of depth direction of the nitride based compound semiconductor layer 12. As ionic species, nitrogen (N), or argon (Ar) is applicable, for example. Further, an amount of dose in the ion implantation is about 1×10¹⁴ (ions/cm²), for example, and accelerating energy is about 100 keV-200 keV, for example.

An insulating layer for passivation (illustration is omitted) is formed on the device isolation region and a device surface. The insulating layer can be formed of a nitride film, an alumina (Al₂O₃) film, an oxide film (SiO₂), or an acid nitride (SiON) film, for example, deposited by the PECVD (Plasma Enhanced Chemical Vapor Deposition) method, for example.

The substrate 10 can use any one of a GaAs substrate, a GaN substrate, a substrate having a GaN epitaxial layer formed on a SiC substrate, a substrate having a GaN epitaxial layer formed on a Si substrate, a substrate having a hetero-junction epitaxial layer which has GaN/AlGaN formed on a SiC substrate, a substrate having a GaN epitaxial layer formed on a sapphire substrate, a sapphire substrate, and a diamond substrate other than the SiC substrate.

As an operating frequency become high as microwave band/millimeter wave band/submillimeter wave band, a pattern length in a longitudinal direction of the gate electrode 24, source electrode 20 and drain electrode 22 is set short. The pattern length is about 25 micrometers-50 micrometers, for example, in millimeter wave band.

(Manufacturing Method)

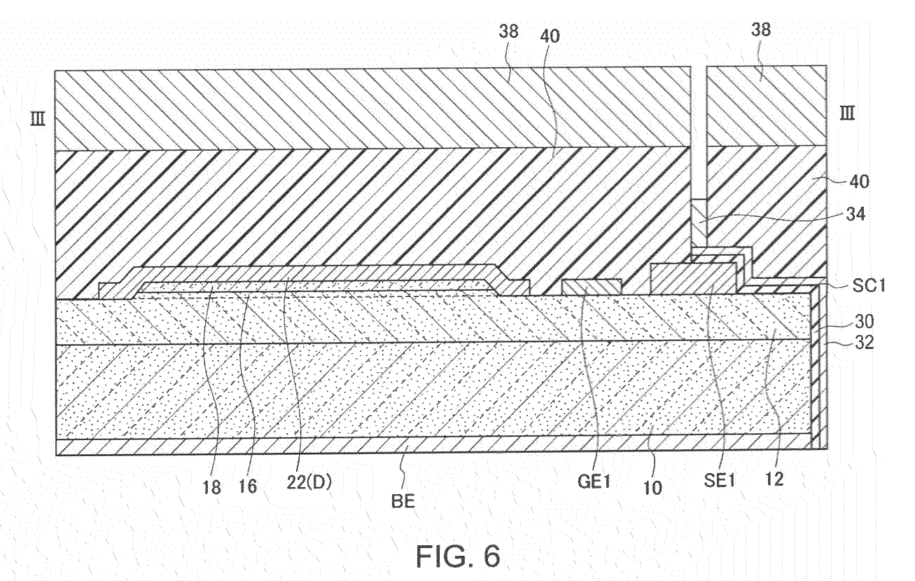

Hereinafter, a manufacturing method of the semiconductor device concerning the first embodiment of the invention is explained in detail with reference to FIG. 6.

(a) TMG (trimethyl gallium) and ammonia gas are passed on the SiC substrate 10 to form the GaN layer 12 which is the nitride based compound semiconductor layer of a thickness of about 1 micrometer, for example, by epitaxial growth.

(b) Next, TMAl (trimethyl aluminum) and ammonia gas are passed to form the aluminum gallium nitride layer (AlₓGa₁₋ₓN) (0.1≦x≦1) 18 of about 30% of Al composition ratio, for example, and of a thickness of about 20 nm-100 nm, for example, on the GaN layer 12 by the epitaxial growth. Thereby, the 2DEG layer 16 is formed. Further, unnecessary portions of the aluminum gallium nitride layer 18 and the GaN layer 12 are removed by a well-known etching method so that the region used as the active region AA may remain.

(c) Next, Ti/Al are vapor-deposited on the GaN layer 12 and the aluminum gallium nitride layer 18. This metal laminated film is etched by a well-known etching method so that the source electrode 20 and the drain electrode 22 which have the plurality of fingers respectively may be formed on the active region AA. In this etching, on the GaN layer 12 located in the direction which the source electrode 20 and the drain electrode 22 extend, the source terminal electrodes SE1, SE2, SE3, SE4 which bundle the plurality of fingers of the source electrode 20 and are connected to the source electrode 20, and the drain terminal electrode DE which bundles the plurality of fingers of the drain electrode 22 and is connected to the drain electrode 22 are formed. The source electrode 20 and the aluminum gallium nitride layer 18 form the ohmic contact, and the drain electrode 22 and the aluminum gallium nitride layer 18 form the ohmic contact.

(d) Next, Ni/Au are vapor-deposited on the GaN layer 12 and the aluminum gallium nitride layer 18 on which the source electrode 20, the drain electrode 22, the source terminal electrodes SE1, SE2, SE3, SE4 and the drain terminal electrode DE were formed. This metal laminated film is etched by the well known etching method so that the gate electrode 24 which has the plurality of fingers may be formed on the active region AA and the gate terminal electrodes GE1, GE2, GE3 which bundle the plurality of fingers of the gate electrode and are connected to the gate electrode may be formed on the GaN layer 12 located in the direction which the gate electrode 24 extends. The gate electrode 24 and the aluminum gallium nitride layer 18 form the schottky contact.

(e) Next, the substrate 10 is polished from the back to thin the substrate 10 using CMP (Chemical Mechanical Polishing) technique. Here, a thickness of the thinned substrate 10 is about 50 micrometers-100 micrometers, for example.

(f) Next, a ground conductor BE is formed on the back of the substrate 10 using the vacuum deposition technique etc.

(g) Next, in order to form the barrier metal layer, the Ti/Pt layer 30, for example, is formed on the entire surface of the semiconductor device and the end face of the substrate 10 at the source terminal electrode side. Not the Ti/Pt layer but a Ti layer may be used for the metal layer for forming the barrier metal layer. In order to form the metal layer for grounding, the Au layer 32, for example, is formed on the Ti/Pt layer 30. Next, by a well-known etching method which uses photoresist, the Ti/Pt layer 30 and the Au layer 32 are patterned so that the Ti/Pt layer 30 and the Au layer 32 may overlap with partial region of the source terminal electrodes SE1, SE2, SE3, SE4. Thereby, the barrier metal layers 30 and the metal layer 32 for grounding are formed. And thus, the end face electrodes SC1, SC2, SC3, SC4 which extend on the source terminal electrodes SE1, SE2, SE3, SE4 are formed.

(h) Next, a photoresist layer 40 is applied on the entire surface of the semiconductor device, and as shown in FIG. 6, the photoresist layer 40 is patterned so that the end face electrodes SC1, SC2, SC3, SC4 may be exposed in part on the boundary between the end face electrodes SC1, SC2, SC3, SC4 and the source terminal electrodes SE1, SE2, SE3, SE4. Next, an Au layer 38, for example, is vapor-deposited on the entire surface of the semiconductor device. Then, the Au layer 38 on the photoresist layer 40 is removed with the photoresist layer 40 by a lift off method. Thereby, the projections 34 as shown in FIG. 2 are formed.

The semiconductor device concerning the first embodiment shown in FIGS. 1 and 2 is obtained by the above (a)-(h) steps.

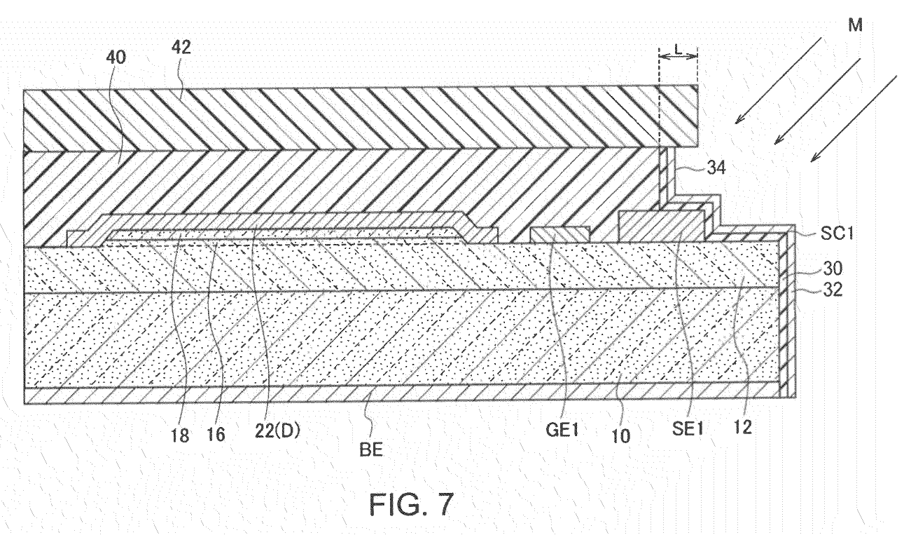

Another method which forms the projections 34 is explained with reference to FIG. 7. After forming the ground conductor BE on the back of the substrate 10 by the (f) step above-mentioned, the end face electrodes SC1, SC2, SC3, SC4 and the projection are formed simultaneously. In this method, after forming the ground conductor BE, the photoresist layer 40 is applied on the surface of the semiconductor device, and the photoresist layer 40 is patterned to a predetermined shape of the end face electrodes SC1, SC2, SC3, SC4. Further, a photoresist layer 42 is applied on the surface of the semiconductor device including the photoresist layer 40. The photoresist layer 42 is patterned to the predetermined shape similar to the end face electrodes SC1, SC2, SC3, SC4 so that the photoresist layer 42 may overhang only distance L to the resist layer 40.

Next, using photoresist layers 40, 42 as a mask and using an oblique vapor-depositing method, the Ti/Pt layer 30 is formed in order to form the barrier layer and also the Au layer 32 is formed on the Ti/Pt layer 30 in order to form the metal layer for grounding. The photoresist layers 40, 42, the Ti/Pt layer 30 and the Au layer 32 on the photoresist layer 42 are removed. Thereby, the end face electrodes SC1, SC2, SC3, SC4 which extend on the source terminal electrodes SE1, SE2, SE3, SE4, and the projections 34 which is formed unitary with the end face electrodes SC1, SC2, SC3, SC4, are obtained.

FIG. 7 shows the example which uses two photoresist layers, the invention, however, may use three or more photoresist layers.

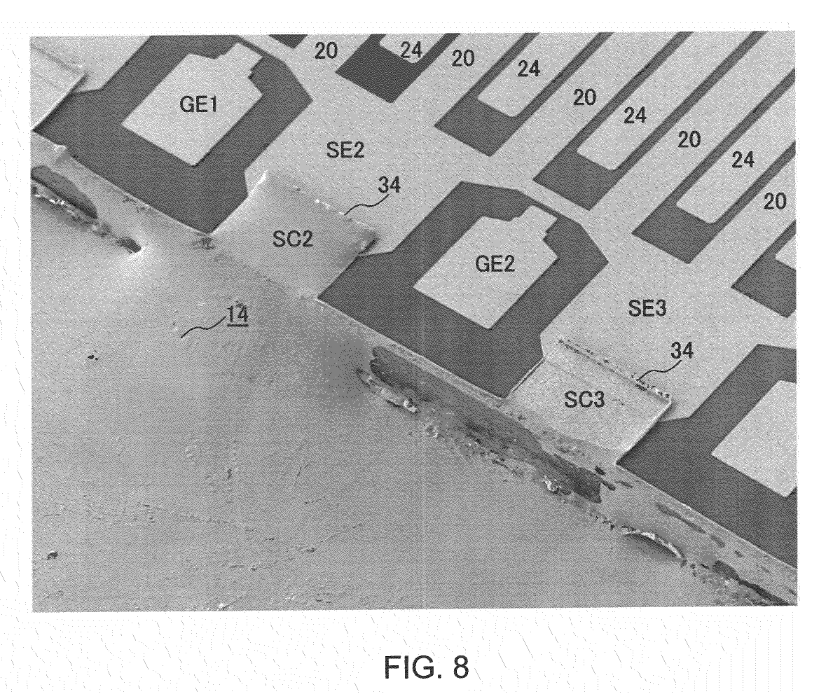

FIG. 8 shows an SEM photograph of a test sample of a semiconductor device and shows an effective result of the projection 34. The test sample is used in FIG. 8, so that the gate terminal electrodes GE1, GE2, GE3 are not connected to each gate electrode 24. A height of the projection 34 is about 0.5 micrometers or more and 3 micrometers or less, for example. A width of the projection 34 is about 0.5 micrometers or more and 3 micrometers or less, for example.

As shown in FIG. 8, in die bonding, a phenomenon in which the solder 14 rises on the end face electrode SC1, SC2, SC3, SC4 is confirmed. However, the solder 14 is prevented from spreading to up to the source terminal electrode SE1, SE2, SE3, SE4 by the projections 34 arranged on the end face electrodes SC1, SC2, SC3, SC4 at the interface between the end face electrodes SC1, SC2, SC3, SC4 and the source terminal electrodes SE1, SE2, SE3, SE4.

According to the semiconductor device concerning the first embodiment, the solder is prevented from reaching the source terminal electrodes SE1, SE2, SE3, SE4 and the source electrode 20 by the projections 34. As a result, a reaction of the Au layer which constitutes the source terminal electrodes SE1, SE2, SE3, SE4 and the source electrode 20, and the material, such as AuSn, included in the solder 14 is inhibited, and an increase in the source resistance is prevented.

According to the semiconductor device concerning the first embodiment, the semiconductor device for microwave band/millimeter wave band/submillimeter wave band which can prevent the increase in the source resistance, and the manufacturing method for the same can be provided.

### Second Embodiment

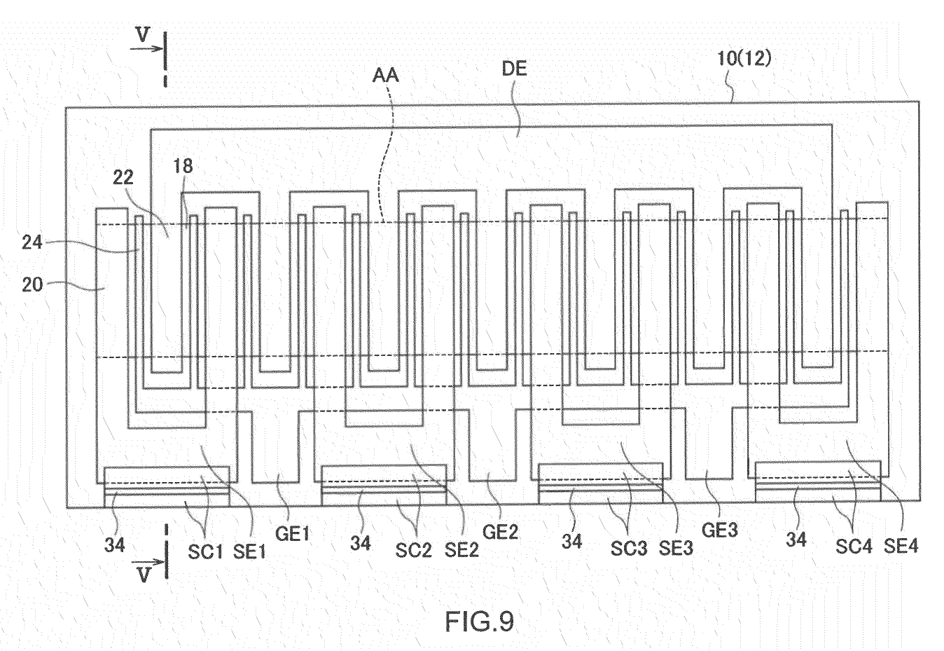

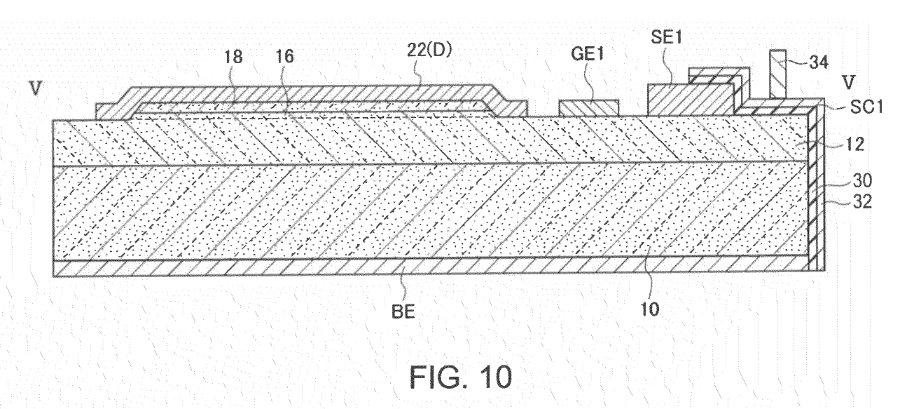

FIG. 9 shows the schematic plane pattern structure of a semiconductor device concerning the second embodiment, and FIG. 10 shows a schematic cross sectional structure taken along a V-V line in FIG. 9.

End face electrodes SC1, SC2, SC3, SC4 are formed to extend on source terminal electrodes SE1, SE2, SE3, SE4 and a nitride based compound semiconductor layer 12. The end face electrodes SC1, SC2, SC3, SC4 are formed on an end face of a substrate 10. Projections 34 are arranged on the end face electrodes SC1, SC2, SC3, SC4 which are formed to extend on the nitride based compound semiconductor layer 12. The projections 34 are formed in the full width of the end face electrodes SC1, SC2, SC3, SC4 in a direction along the end face of the substrate 10.

A manufacturing method of the semiconductor device concerning the second embodiment is the same as that of the first embodiment, so that an overlapping explanation is omitted.

The projections 34 are formed on the end face electrodes SC1, SC2, SC3, SC4 after forming the end face electrodes SC1, SC2, SC3, SC4. The second embodiment differs from the first embodiment in that the projections 34 are formed on the end face electrodes SC1, SC2, SC3, SC4 which are formed to extend on the nitride based compound semiconductor layer 12.

According to the semiconductor device concerning the second embodiment, solder used in die bonding is prevented from reaching the source terminal electrode and a source electrode by the projection 34. Thereby, the semiconductor device for microwave band/millimeter wave band/submillimeter wave band which can prevent the increase in the source resistance, and the manufacturing method for the same can be provided.

### Third Embodiment

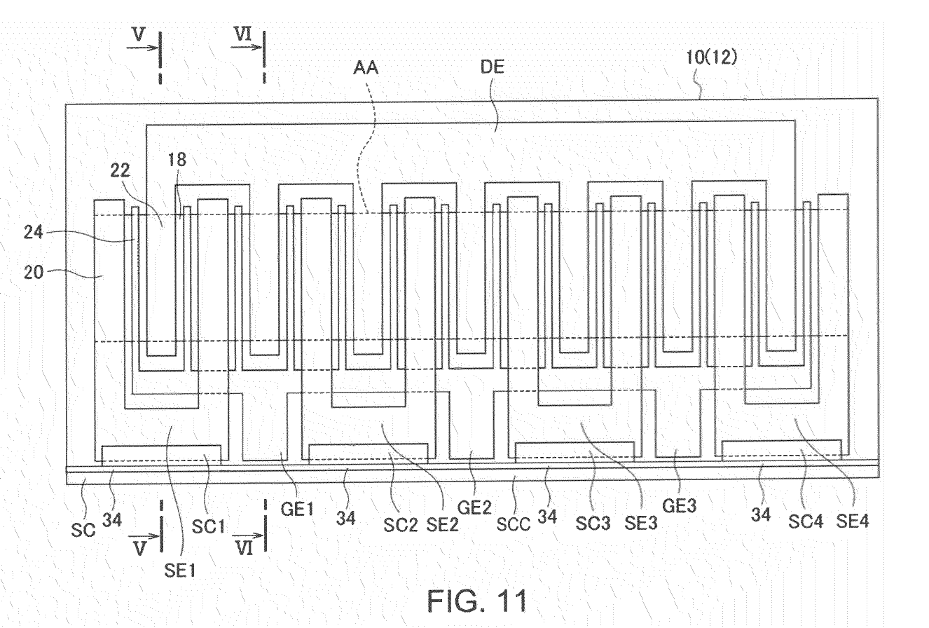

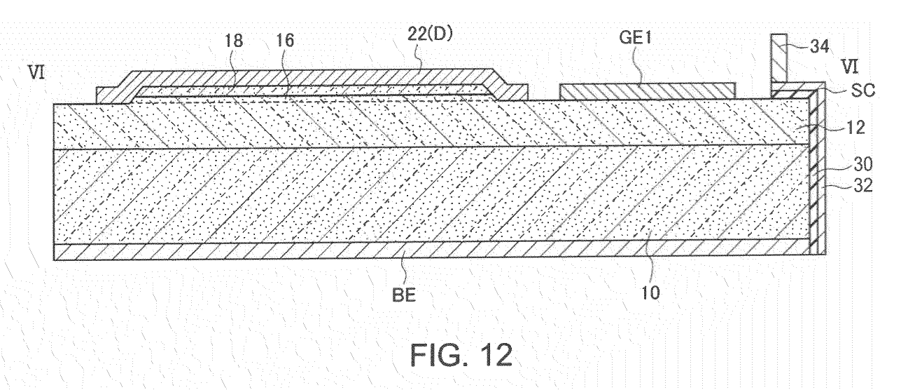

FIG. 11 shows a schematic plane pattern structure of a semiconductor device concerning the third embodiment, and FIG. 12 shows a schematic cross sectional structure taken along a VI-VI line in FIG. 11. The schematic cross sectional structure taken along a V-V line in FIG. 11 is the same as that of FIG. 10.

End face electrode SC has regions SC1, SC2, SV3, SC4 which are formed to extend on source terminal electrodes SE1 SE2, SE3, SE4 and a region SCC which extends on a nitride based compound semiconductor layer 12 and is formed in common to a plural of source terminal electrodes SE1, SE2, SE3, SE4. A projection 34 is arranged along an end face of a substrate 10 in stripe shape on the region SCC of the end face electrode SC formed on the nitride based compound semiconductor layer 12.

A manufacturing method of the semiconductor device concerning the third embodiment is the same as that of the first embodiment, so that an overlapping explanation is omitted.

The region SCC of the end face electrode SC extends on the nitride based compound semiconductor layer 12 and is formed in common to a plurality of the source terminal electrodes SE1, SC2, SC3, SE4. Further, the regions SC1, SC2, SC3, SC4 of the end face electrode SC are formed to extend on the source terminal electrodes SE1, SE2, SE3, SE4. The third embodiment differs from the first embodiment in that the projection 34 is formed in stripe on the region SCC of the end face electrode SC which is formed on the nitride based compound semiconductor layer 12.

According to the semiconductor device concerning the third embodiment, solder used in die bonding is prevented from reaching the source terminal electrode and the source electrode by the projection 34. Thereby, the semiconductor device for microwave band/millimeter wave band/submillimeter wave band which can prevent the increase in the source resistance and the manufacturing method for the same can be provided.

### Fourth Embodiment

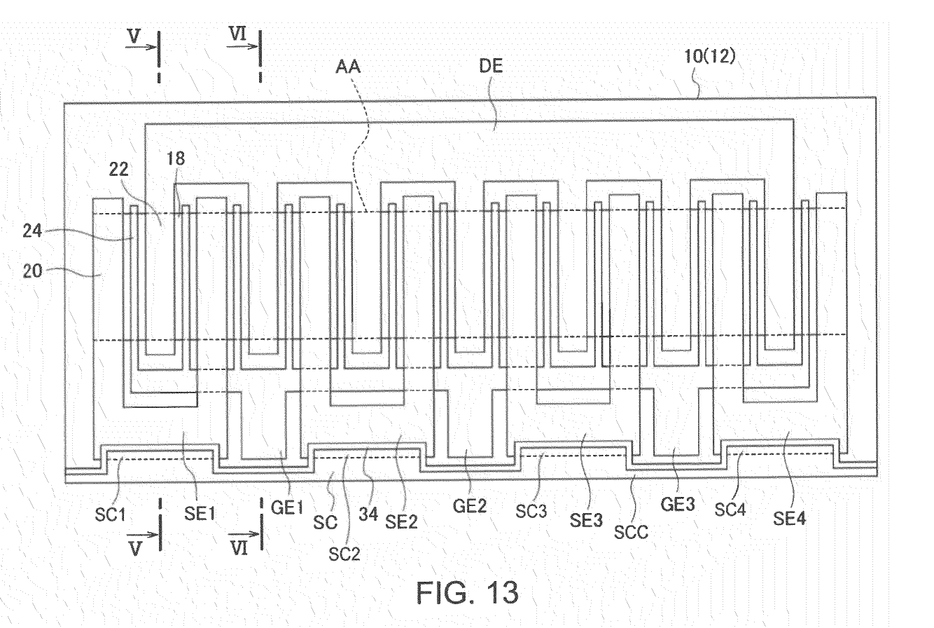

FIG. 13 shows a schematic plane pattern structure of a semiconductor device concerning the fourth embodiment. A schematic cross sectional structure taken along a V-V line in FIG. 13 is similarly expressed as the schematic cross sectional structure of FIG. 2.

End face electrode SC has regions SC1, SC2, SC3, SC4 which are formed to extend on source terminal electrode SE1, SE2, SE3, SE4, and a region SCC which extends on a nitride based compound semiconductor layer 12 and is formed in common to a plurality of source terminal electrodes SE1, SE2, SE3, SE4. Projection 34 is arranged on the regions SC1, SC2, SC3, SC4 of the end face electrode SC on the boundary between the end face electrode SC which is formed to extend on the source terminal electrodes SE1, SE2, SE3, SE4 and the source terminal electrodes SE1, SE2, SE3, SE4, and on the region SCC of the end face electrode SC which is formed to extend on the nitride based compound semiconductor layer 12. Portions of the projection 34 on the regions SC1, SC2, SC3, SC4 and portions of the projection 34 on the region SCC are connected. The projection 34 is formed on the end face electrode SC along an active region AA side edge of the end face electrode SC. The structure of other each part is the same as that of the first embodiment, so that an overlapping explanation is omitted.

The manufacturing method of the semiconductor device concerning the fourth embodiment is the same as that of the first embodiment, so that an overlapping explanation is omitted.

In a process of forming the end face electrode SC, the end face electrode SC is formed to extend on the source terminal electrode SE1, SE2, SE3, SE4, and extends on the nitride based compound semiconductor layer 12, and is formed in common to a plurality of the source terminal electrodes SE1, SE2, SE3, SE4. In the process to form the projection 34, the fourth embodiment differs from the first embodiment in that the projection 34 is formed on the end face electrode SC on the boundary between the end face electrode SC which is formed to extend on the source terminal electrodes SE1, SE2, SE3, SE4 and the end source terminal electrodes SE1, SE2, SE3, SE4, and is formed on the end face electrode SC formed on the nitride based compound semiconductor layer 12.

According to the semiconductor device concerning the fourth embodiment, solder used in die bonding is prevented from reaching the source terminal electrode and the source electrode by the projection. Thereby, the semiconductor device for microwave band/millimeter wave band/submillimeter wave band which can prevent the increase in the source resistance and the manufacturing method for the same can be provided.

### Fifth Embodiment

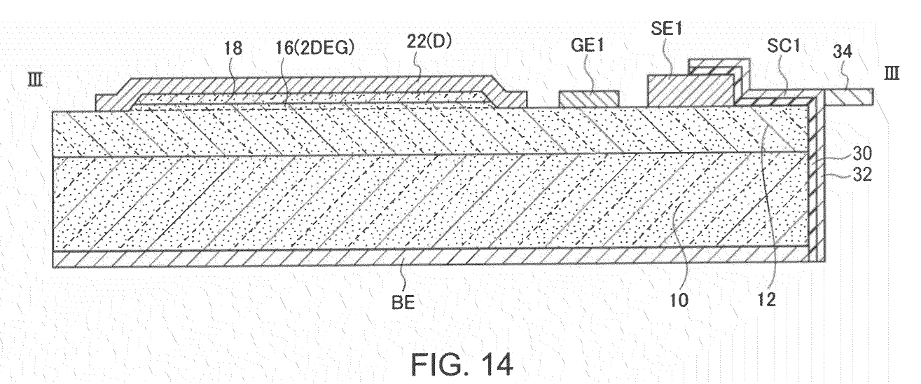

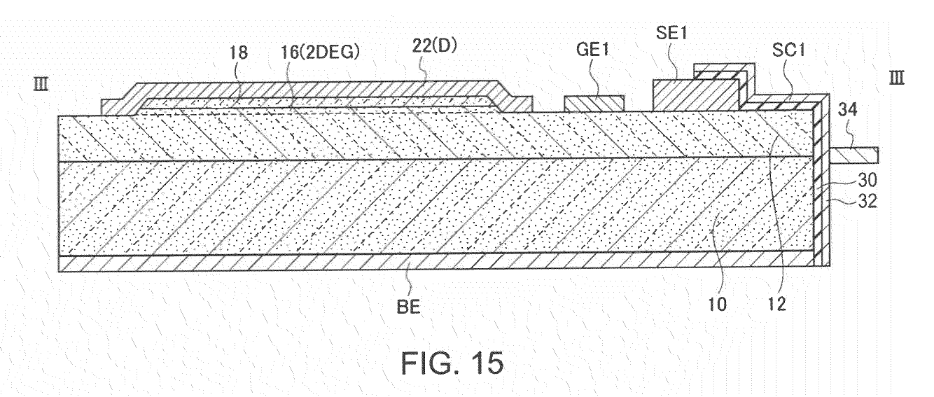

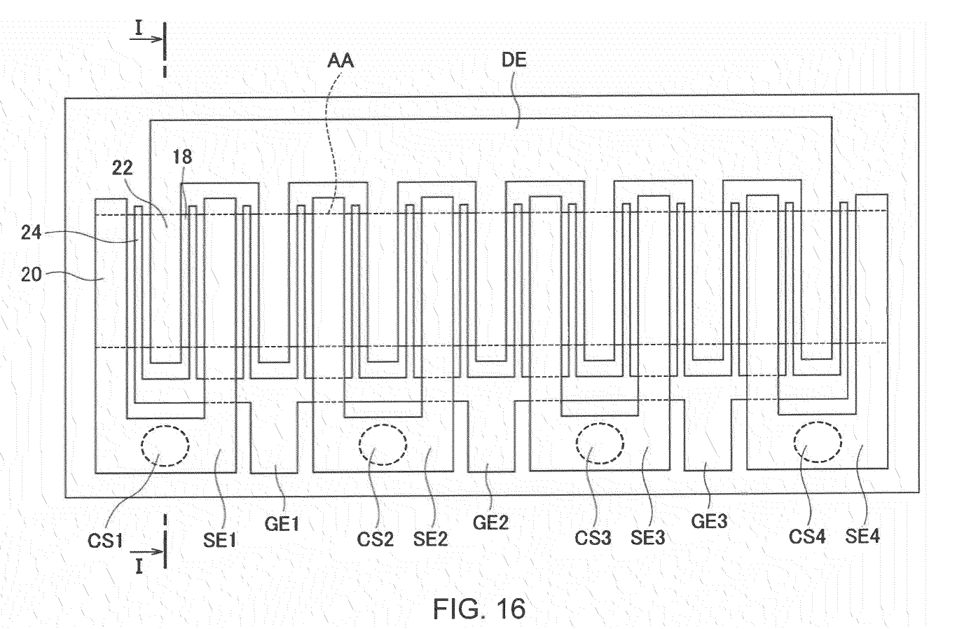

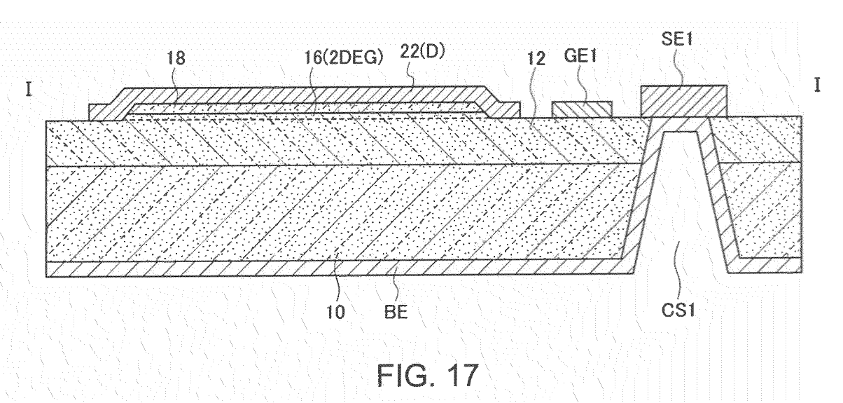

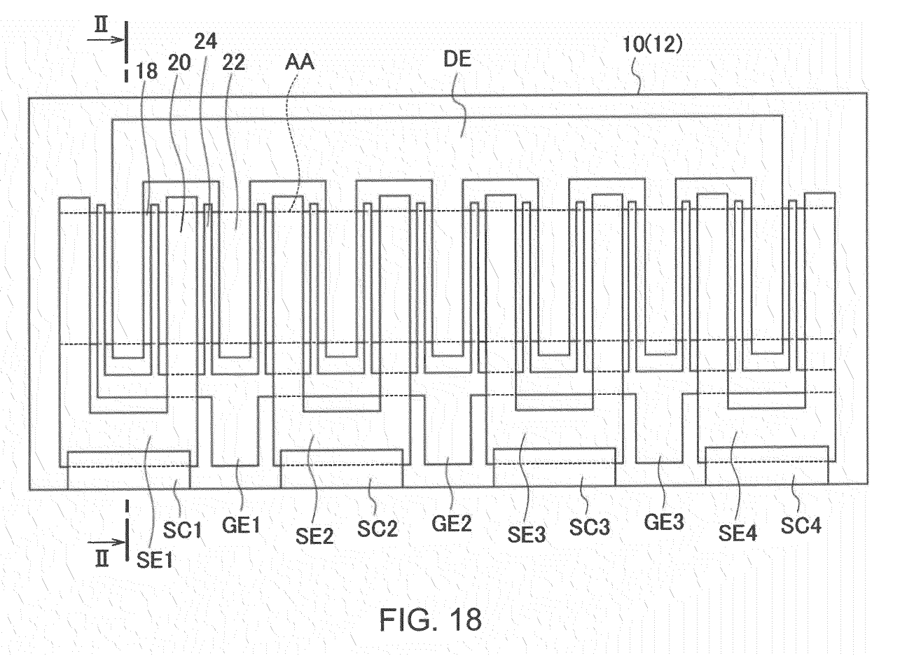

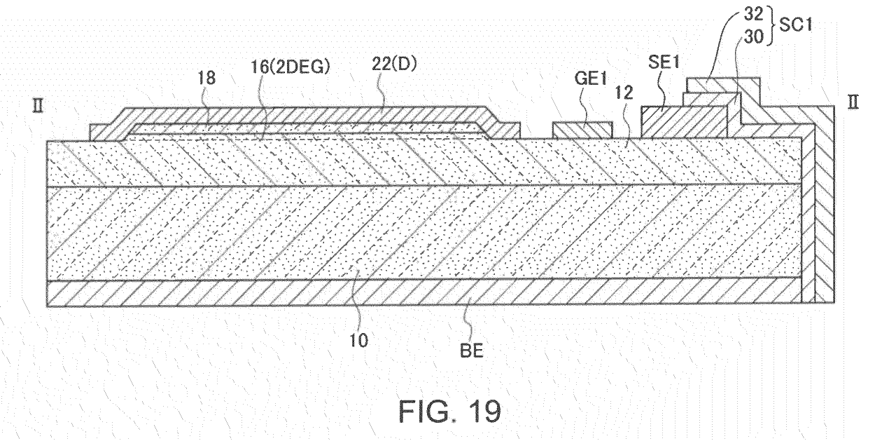

FIG. 14 shows a schematic cross sectional structure of a semiconductor device concerning a fifth embodiment. FIG. 14 corresponds to the schematic cross sectional structure taken along the III-III line in FIG. 1, and positions where projections 34 are arranged differ from FIG. 2.

The projection 34 is arranged on an end face electrode SC1 at a corner part of the end face electrode SC1 arranged on an end face of a substrate 10. That is, the projection 34 is formed on the end face electrode SC1 at the corner part which an upper surface of the substrate 10 and the end face of the substrate 10 intersect. The structure of other each part is the same as that of the first embodiment, so that an overlapping explanation is omitted.

The manufacturing method of the semiconductor device concerning the fifth embodiment is the same as that of the first embodiment, so that an overlapping explanation is omitted.

According to the semiconductor device concerning the fifth embodiment, solder used in die bonding is prevented from reaching the source terminal electrode and the source electrode by the projection. Thereby, the semiconductor device for microwave band/millimeter wave band/submillimeter wave band which can prevent the increase in the source resistance and the manufacturing method for the same can be provided.

### Sixth Embodiment

FIG. 15 shows a schematic cross sectional structure of a semiconductor device concerning a sixth embodiment. FIG. 15 corresponds to the schematic cross sectional structure taken along the III-III line in FIG. 1, and positions where projections 34 are arranged differ from FIG. 2.

The projection 34 is arranged on a perpendicular end face of an end face electrode SC1 arranged on an end face of a substrate 10. The structure of other each part is the same as that of the first embodiment, so that an overlapping explanation is omitted.

The manufacturing method of the semiconductor device concerning the sixth embodiment is the same as that of the first embodiment, so that an overlapping explanation is omitted.

According to the semiconductor device concerning the sixth embodiment, solder used in die bonding is prevented from reaching the source terminal electrode and the source electrode by the projection. Thereby, the semiconductor device for microwave band/millimeter wave band/submillimeter wave band which can prevent the increase in the source resistance and the manufacturing method for the same can be provided.

In the first embodiment to sixth embodiment, the end face electrodes SC1, SC2, SC3, SC4 are arranged at one side of the substrate 10 which exists in an extension direction of the plurality of fingers of the gate electrode 24, the source electrode 20 and the drain electrode 22. However, the end face electrodes SC1, SC2, SC3, SC4 may be arranged not only at one side but at two sides which face each other. The end face electrodes SC1, SC2, SC3, SC4 may be arranged at one side of the substrate 10 in the direction which intersects perpendicularly with the extension direction of the plurality of fingers of the gate electrode 24, the source electrode 20 and the drain electrode 22, or at two sides which face each other.

In the first embodiment to sixth embodiment, only one active region AA on which the gate electrode 24, the source electrode 20 and the drain electrode 22 having the plurality of fingers are arranged is arranged. However, a plurality of active regions AA may be arranged on the substrate 10 in a plurality of lines or matrix form.

In addition, it is obvious that the semiconductor device of the invention is applied to not only the FET, the HEMT and the MESFET, but amplifying device, such as an LDMOS (Lateral Doped Metal-Oxide-Semiconductor Field Effect Transistor) and an HBT (Hetero-junction Bipolar Transistor), and a MEMS (Micro Electro Mechanical Systems) device etc.

The semiconductor device of the invention is applicable to a broad field, such as an internal matching type power amplifying device, a power MMIC (Monolithic Microwave Integrated Circuit), a microwave power amplifier, a millimeter wave power amplifier, a high frequency MEMS device, etc.

Other embodiments or modifications of the invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising:
a substrate;
a nitride based compound semiconductor layer arranged on the substrate;
an active region arranged on the nitride based compound semiconductor layer and having an aluminum gallium nitride layer (AlₓGa₁₋ₓN) (0.1≦x≦1);
a gate electrode arranged on the active region;
a source electrode arranged on the active region;
a drain electrode arranged on the active region;
a gate terminal electrode arranged on the nitride based compound semiconductor layer in an extension direction of the gate electrode, and being connected to the gate electrode;
a source terminal electrode arranged on the nitride based compound semiconductor layer in an extension direction of the source electrode, and being connected to the source electrode;
a drain terminal electrode arranged on the nitride based compound semiconductor layer in an extension direction of the drain electrode, and being connected to the drain electrode;
an end face electrode arranged on an end face of the substrate in a source terminal electrode side, and being connected to the source terminal electrode; and
a projection arranged on the end face electrode and being configured to prevent solder used in die bonding from reaching the source terminal electrode.

2. A semiconductor device, comprising:
a substrate;
a nitride based compound semiconductor layer arranged on the substrate;
an active region arranged on the nitride based compound semiconductor layer, and having an aluminum gallium nitride layer (AlₓGa_{1·x}N) (0.1≦x≦1);
a gate electrode arranged on the active region and having a plurality of fingers;
a source electrode arranged on the active region and having a plurality of fingers;
a drain electrode arranged on the active region and having a plurality of fingers;
a gate terminal electrode arranged on the nitride based compound semiconductor layer in an extension direction of the gate electrode, and bundling the plurality of fingers of the gate electrode;
a source terminal electrode arranged on the nitride based compound semiconductor layer in an extension direction of the source electrode, and bundling the plurality of fingers of the source electrode;
a drain terminal electrode arranged on the nitride based compound semiconductor layer in an extension direction of the drain electrode, and bundling the plurality of fingers of the drain electrode;
an end face electrode arranged on an end face of the substrate in a source terminal electrode side, and being connected to the source terminal electrode; and
a projection arranged on the end face electrode and being configured to prevent solder used in die bonding from reaching the source terminal electrode.

3. The semiconductor device according to claim 1 or claim 2, wherein the end face electrode is formed to extend on the source terminal electrode, and the projection is arranged on the end face electrode formed to extend on the source terminal electrode.

4. The semiconductor device according to claim 1 or claim 2, wherein the end face electrode is formed to extend on the source terminal electrode, and the projection is arranged on the end face electrode which is formed to extend on the source terminal electrode on a boundary between the source terminal electrode and the end face electrode.

5. The semiconductor device according to claim 1 or claim 2, wherein the end face electrode has a first region formed to extend on the source terminal electrode and a second region formed to extend on the nitride based compound semiconductor layer, and the projection is arranged on the second region of the end face electrode.

6. The semiconductor device according to claim 1 or claim 2, wherein the end face electrode has a first region formed to extend on the source terminal electrode and a second region which extends on the nitride based compound semiconductor layer and is formed in common to a plurality of source terminal electrodes, and the projection is arranged on the second region of the end face electrode in stripe shape.

7. The semiconductor device according to claim 1 or claim 2, wherein the end face electrode has a first region formed to extend on the source terminal electrode and a second region which extends on the nitride based compound semiconductor layer and is formed in common to a plurality of source terminal electrodes, and the projection is arranged on the first region of the end face electrode on a boundary of the source terminal electrode and the first region of the end face electrode and is arranged on the second region of the end face electrode.

8. The semiconductor device according to claim 1 or claim 2, wherein the projection is arranged on the end face electrode at a corner part which a surface of the substrate and the end face of the substrate intersect.

9. The semiconductor device according to claim 1 or claim 2, wherein the projection is arranged on the end face electrode arranged on the end face of the substrate.

10. The semiconductor device according to claim 1 or claim 2, wherein the end face electrode has a barrier metal layer and the metal layer for grounding arranged on the barrier metal layer.

11. The semiconductor device according to claim 10, wherein the barrier metal layer includes a Ti layer, or a Ti/Pt layer, and the metal layer for grounding includes an Au layer.

12. The semiconductor device according to claim 1 or claim 2, wherein the substrate includes any one of a SiC substrate, a GaAs substrate, a GaN substrate, a substrate having a GaN epitaxial layer formed on a SiC substrate, a substrate having a GaN epitaxial layer formed on a Si substrate, a substrate having a hetero-junction epitaxial layer of GaN/AlGaN formed on a SiC substrate, a substrate having a GaN epitaxial layer formed on a sapphire substrate, a sapphire substrate or a diamond substrate.

13. A method for manufacturing a semiconductor device, comprising:
forming a nitride based compound semiconductor layer on a substrate;
forming an active region including an aluminum gallium nitride layer (AlₓGa₁₋ₓN) (0.1≦x≦1) on the nitride based compound semiconductor layer;
forming a gate electrode on the active region;
forming a source electrode on the active region;
forming a drain electrode on the active region;
forming a gate terminal electrode connected to the gate electrode on the nitride based compound semiconductor layer in an extension direction of the gate electrode;
forming a source terminal electrode connected to the source electrode on the nitride based compound semiconductor layer in an extension direction of the source electrode;
forming a drain terminal electrode connected to the drain electrode on the nitride based compound semiconductor layer in an extension direction of the drain electrode;
forming the end face electrode connected to the source terminal electrode on the end face of the substrate in a source terminal electrode side; and
forming a projection on the end face electrode, the projection being configured to prevent solder used in die bonding from reaching the source terminal electrode.

14. A method for manufacturing a semiconductor device, comprising:
forming a nitride based compound semiconductor layer arranged on a substrate;
forming an active region including an aluminum gallium nitride layer (AlₓGa₁₋ₓN) (0.1≦x≦1) on the nitride based compound semiconductor layer;
forming a gate electrode having a plurality of fingers on the active region;
forming a source electrode having a plurality of fingers on the active region;
forming a drain electrode having a plurality of fingers on the active region;
forming a gate terminal electrode bundling the plurality of fingers of the gate electrode on the nitride based compound semiconductor layer in an extension direction of the gate electrode;
forming a source terminal electrode bundling the plurality of fingers of the source electrode on the nitride based compound semiconductor layer in an extension direction of the source electrode;
forming a drain terminal electrode bundling the plurality of fingers of the drain electrode on the nitride based compound semiconductor layer in an extension direction of the drain electrode;
forming the end face electrode connected to the source terminal electrode on the end face of the substrate in a source terminal electrode side; and
forming a projection on the end face electrode, the projection being configured to prevent solder used in die bonding from reaching the source terminal electrode.

15. The manufacturing method of the semiconductor device according to claim 13 or claim 14, wherein forming the projection uses a lift off method.

16. The manufacturing method of the semiconductor device according to claim 13 or claim 14, wherein forming the projection uses an oblique vapor deposition method.

17. The manufacturing method of the semiconductor device according to claim 13 or claim 14, wherein the end face electrode is formed to extend on the source terminal electrode in forming the end face electrode, and the projection is formed on the end face electrode formed to extend on the source terminal electrode in forming the projection.

18. The manufacturing method of the semiconductor device according to claim 13 or claim 14, wherein the end face electrode is formed to extend on the source terminal electrode in forming the end face electrode, and the projection is formed on the end face electrode formed to extend on the source terminal electrode on a boundary between the end face electrode formed to extend on the source terminal electrode and the source terminal electrode in forming the projection.

19. The manufacturing method of the semiconductor device according to claim 13 or claim 14, wherein the end face electrode is formed to extend on the nitride based compound semiconductor layer in forming the end face electrode, and the projection is formed on the end face electrode formed to extend on the nitride based compound semiconductor layer in forming the projection electrode.

20. The manufacturing method of the semiconductor device according to claim 13 or claim 14, wherein the end face electrode is formed to extend on the nitride based compound semiconductor layer and is formed in common to a plurality of the source terminal electrodes in forming the end face electrode, and the projection is formed in stripe shape on the end face electrode formed on the nitride based compound semiconductor layer in forming the projection electrode.

21. The manufacturing method of the semiconductor device according to claim 13 or claim 14, wherein a first region of the end face electrode which extends on the source terminal electrode is formed, and a second region of the end face electrode which extends on the nitride based compound semiconductor layer and is in common to a plurality of the source terminal electrodes is formed in the process of forming said end face electrode, a first portion of the projection is formed on a boundary between the source terminal electrode and the first region of the end face electrode, and a second portion of the projection connecting to the first portion of the projection is formed on the second region of the end face electrode in forming said projection.
